(19) United States
(12) Patent Application Publication
(10) Pub. No.: US 2019/0373736 A1
(43) Pub. Date: Dec. 5, 2019

(54) CREATING A CAVITY USING PLASMA GAS

(71) Applicants: Rahul Jain, Gilbert, AZ (US); Kyu Oh Lee, Chandler, AZ (US); Ji Yong Park, Chandler, AZ (US); Sai Vadlamani, Sai, AZ (US)

(72) Inventors: Rahul Jain, Gilbert, AZ (US); Kyu Oh Lee, Chandler, AZ (US); Ji Yong Park, Chandler, AZ (US); Sai Vadlamani, Sai, AZ (US)

(21) Appl. No.: 16/473,573

(22) PCT Filed: Mar. 31, 2017
(86) PCT No.: PCT/US2017/025408

§ 371 Date: Jun. 25, 2019

(51) Int. Cl. H05K 3/00; H01L 23/498; H05K 3/46

(52) U.S. Cl. CPC H05K 3/0041; H01L 23/49822; H01L 21/31138; H05K 2201/0166; H05K 3/4697

(57) ABSTRACT

Described herein are systems and methods for creating a cavity within a substrate. The systems and methods may include passing a plasma gas over a first surface of the substrate. The plasma gas may include a reactant gas. The systems and methods also may include removing a portion of the substrate by reacting the reactant gas with a constituent of the first surface of the substrate, thereby forming the cavity.

### TECHNICAL FIELD

Embodiments described generally herein relate to die manufacturing. Some embodiments relate to using plasma gas to remove portions of a dies substrate thereby creating a cavity within the die substrate.

### BACKGROUND

Laser drilling is a process currently used to create a cavity within a substrate, Laser drilling generally involves heating a material with a laser to melt the material. In a laser drilling process, melting is preferred to vaporization because the energy required for melting is about 25% less than the energy required for vaporization. Regardless of whether melting or vaporization is used, laser drilling is an energy intensive process that can require power inputs having an order of magnitude of MW/cm² to accomplish.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a schematic of a system for forming a cavity in a substrate in accordance with embodiment disclosed herein.

FIG. 2 illustrates an example schematic of a computing device in accordance with embodiment disclosed herein.

FIGS. 3A, 3B, and 3C illustrate an example process flow for creating a cavity within a substrate in accordance with embodiment disclosed herein.

FIGS. 4A, 4B, and 4C illustrate an example process flow for creating a cavity within a substrate in accordance with embodiment disclosed herein.

### DETAILED DESCRIPTION

Today, Package on Package (PoP) architecture provides memory and logic stacking in smartphones and tablets. However, these PoP architectures do not scale efficiently to provide the memory bandwidth required for the new generation multicore application processors. In today's mobile computing platforms that are moving towards multiple core processors along with integrated memory controllers, the processor-memory bandwidth needs to be significantly improved for better performance. Bandwidth may be increased by increasing the memory speed, interconnect density, or both. With power limitations for smartphones/tablets increasing the signal speeds which in turn increases power dissipation may not be a preferred method, hence increasing the input/output (I/O), also known as the interconnect density may be a preferred approach.

Current interconnect technologies, such as stacking with smaller sized solder balls, using solder filled laser drilled vias in the mold cap, or using an interposer are not cost effectively achieving required aspect ratios for fine pitch while overcoming package warpage during soldering.

As disclosed herein, cavities may be created in the bottom substrate for creating enough spaces in the substrate that the die can be inserted to address the gap in PoP interconnect density and manufacturing cost. As a result, an overall height of a device may be reduced and high density PoP interconnect density may be enabled with lower cost.

The cavity in the top of the bottom substrate may enable scalable fine PoP interconnects while having enough stand-off height between top and bottom substrates to accommodate the bottom die. The stand-off height may be adjusted by changing the buildup thickness or increase the number of stack-ups within the cavity layer.

Currently, the method to form a cavity in a substrate is by using a laser drilling process that has relatively slower throughput because it involves drilling each cavity one at a time. The systems and methods disclosed herein are faster at producing a cavity within a substrate.

Disclosed herein are systems and methods for forming a cavity in the top of a bottom substrate to enable scalable fine PoP interconnects. The systems and methods may allow a cavity to be formed at the panel level (i.e., multiple cavities at a time) instead of drilling a single cavity at a time.

Current methods for forming a cavity in a substrate may begin with the application of a paste on a release layer of a surface-1 layer with lamination of the subsequent stack up. A laser cutting process then trims and cuts a predetermined shape to separate the laminated layers from the release layer. Finally, a cap removal process and paste stripping process can be performed to remove the release layer.

As disclosed herein, instead of laser drilling a cavity, a plasma process may be used for trimming and cutting a predetermined shape to separate the laminated layers from the release layer. Using a plasma process as disclosed herein is better than laser drilling because multiple cavities in a panel may be formed at once instead of one at a time. Stated another way, multiple cavities may be formed in parallel instead of in series, Forming multiple cavities at once using a plasma process may increase the throughput as compared to the current laser drilling methods.

Also, the plasma process may eliminate the use a metal trim layer to act as a stop layer that is needed for the laser drilling process. For example, in a laser drilling process, a metal layer is used to control laser penetration and/or prevent the laser from drilling into adjacent layers. Using the systems and methods disclosed herein, the release layer may act as a buffer layer for the plasma cavity drilling step. Since no metal layer is needed to act as a stop layer, the buildup layer normally used as for the metal stop layer may be used for routing and can in-fact reduce the metal layer count by at least one, The reduction in the metal layer count may reduce the overall z-height of the die.

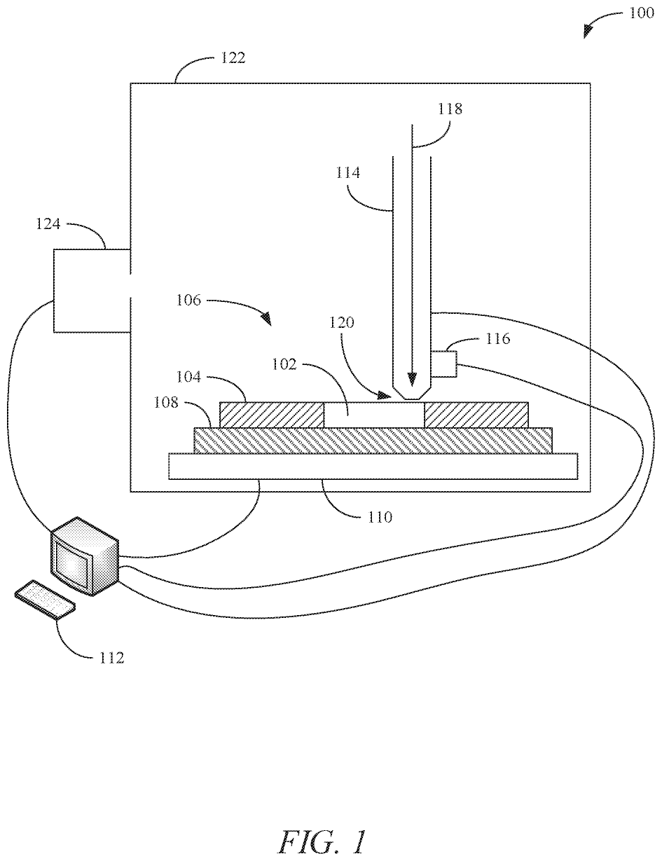

Turning now to the figures, FIG. 1 illustrates a schematic of a system 100 for forming a cavity 102 in a substrate 104 in accordance with embodiments disclosed herein. The substrate may be a component of a die 106 that may include a release layer 108. As shown in FIG. 1, the system 100 may include a platform 110 in electrical communication with a computing device 112. The computing device 112 may also be in electrical communication with a plasma jet 114.

During operation, the computing device 112 may send and receive electrical signals to and from the platform 110 and the plasma jet 114. The electrical signals can include data that controls movement of the platform 110 and the plasma jet 114. For example, the electrical signals may cause the platform 110 to translate beneath a stationary plasma jet 114. In addition, the electrical signals may cause the plasma jet 114 to translate above a stationary platform 110. Furthermore, the electrical signals may cause both the plasma jet 114 and the platform 110 to translate relative to one another. The translation may be cause by motors or other actuators not shown.

The computing device 112 may also be in electrical communication with a sensor 116. While FIG. 1 shows a single sensor, the computing device 112 may communicate with multiple sensors. The sensor 116 may monitor various parameters of the system 100. For example, the sensor 116 may monitor a temperature at the substrate 104 where the cavity 102 is being formed. In addition, the sensor 116 may monitor a composition of a plasma gas flow 118. For instance, the plasma gas flow 118 may be a composition of gases. For instance, the plasma gas within the plasma gas flow 118 may be a binary mixture composed of a reactant gas and a carrier gas. The carrier gas may an inert gas such as, but not limited to, helium, neon, argon, krypton, xenon, and nitrogen. The reactant gas may be any gas that reacts with the substrate 104 such as, but not limited to, fluorine, tetrafluoromethane, methane, and ammonia. The sensor 114 may monitor a composition of the various constituents of the plasma gas. The computing device 112 may transmit signals to the plasma jet 114 that adjusts a flowrate of any constituent of the plasma gas to achieve a desired composition.

As disclosed herein, the platform 110 and/or the plasma jet 114 may be translated relative to one another. During the translation, the plasma jet 114 in communication with the computing device 112 may create a plasma 120. The plasma 120 may react with the substrate 104 to form the cavity 102 within the substrate. The depth of the cavity 102 may be a function of the speed of the plasma jet 114 and platform 110, the concentration of the reactant gas, etc. For example, the reactant gas may be a limiting reagent and at higher concentrations, more reactant is present to remove more of the substrate 104, thereby forming a deeper cavity. If the concentration of the reactant gas is low, less of the substrate 104 may be removed, thereby forming a shallower cavity. Other factors such as, but not limited to, pressure (including partial pressure), temperature, oxidation state, etc., may be manipulated to control the cavity depth and speed at which the plasma jet 114 may traverse the substrate 104 to achieve a desired cavity depth.

One or more of the various components of the system 100 may be enclosed within a chamber 122. The chamber 122 may be connected to a vacuum system 124, which may be in electrical communication with the computing device 112. The vacuum system 124 may create a vacuum within the chamber 122. The vacuum created by the vacuum system 12.4 may allow the products of the reaction between the plasma 120 and the substrate 104 to be removed from the chamber 122. For example, as the plasma 120 reacts with the substrate 104, the product formed may be a gas. As such, the vacuum system 124 may evacuate the gas while maintaining a vacuum or negative pressure within the chamber 122.

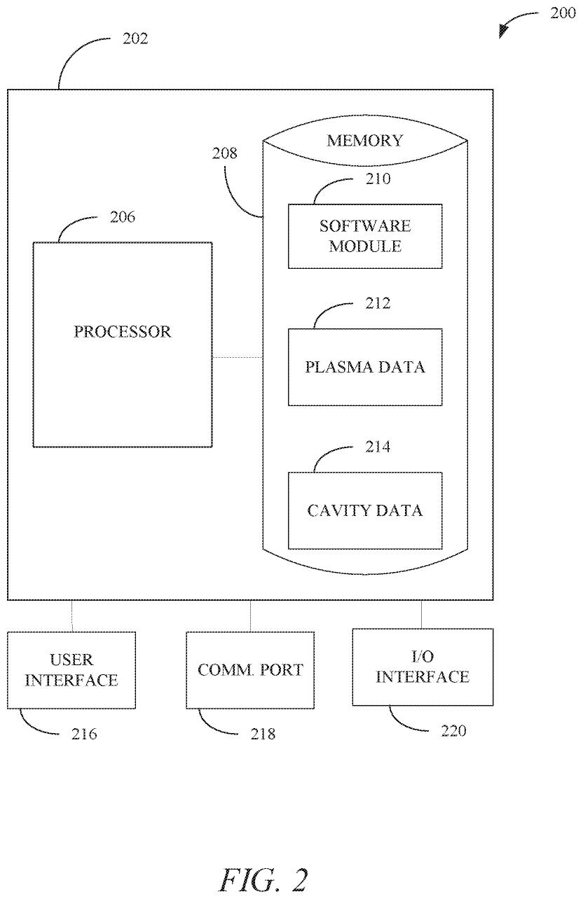

FIG. 2 shows an example schematic of the computing device 112 consistent with embodiments disclosed herein, The computing device 112 may be a portable computing device, a desktop computer, or other microprocessor based computing device. As such, the computing device 112 may located proximate the chamber 122 or located remotely from the chamber 122. For example, the computer device 112 may be located in a control room proximate an assembly area where the die 106 may be fabricated such that a technician may monitor the system 100.

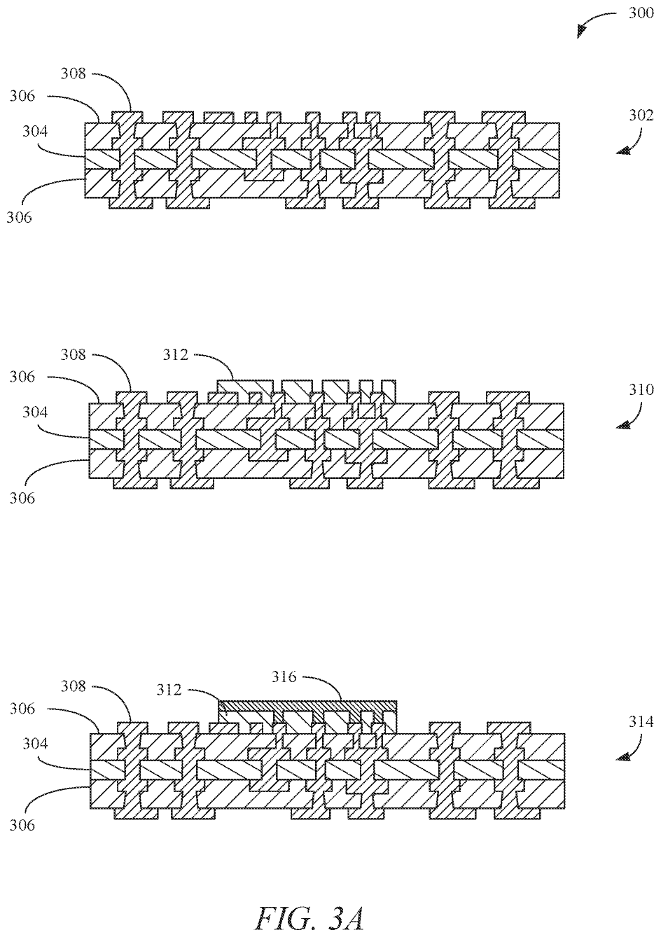

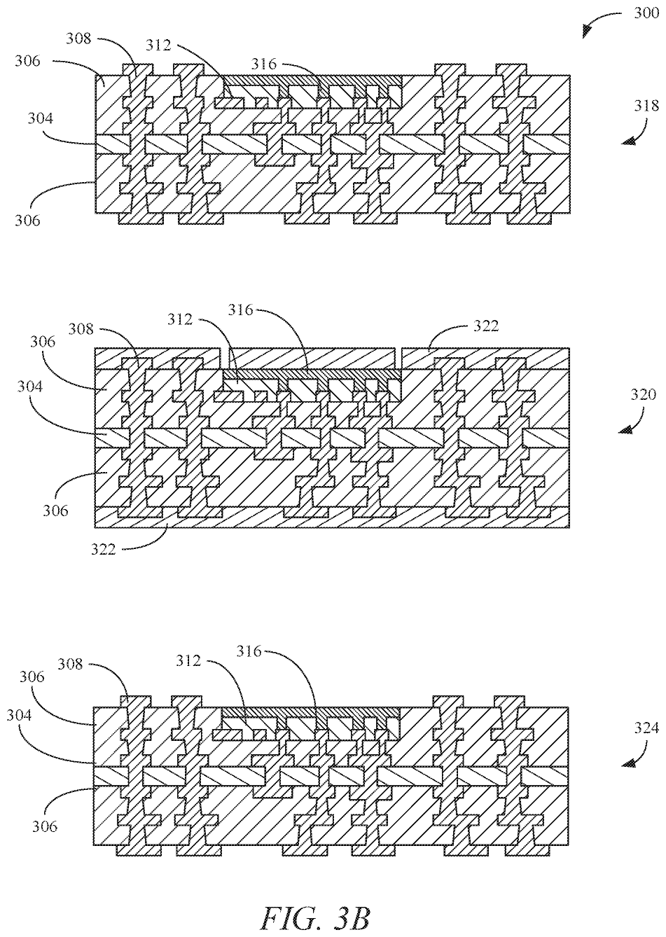

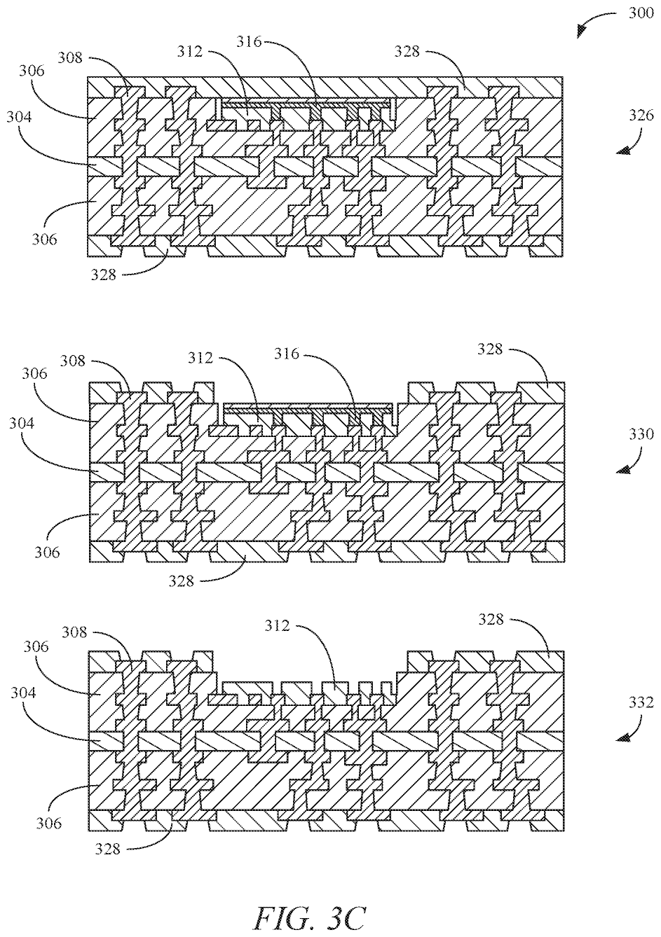

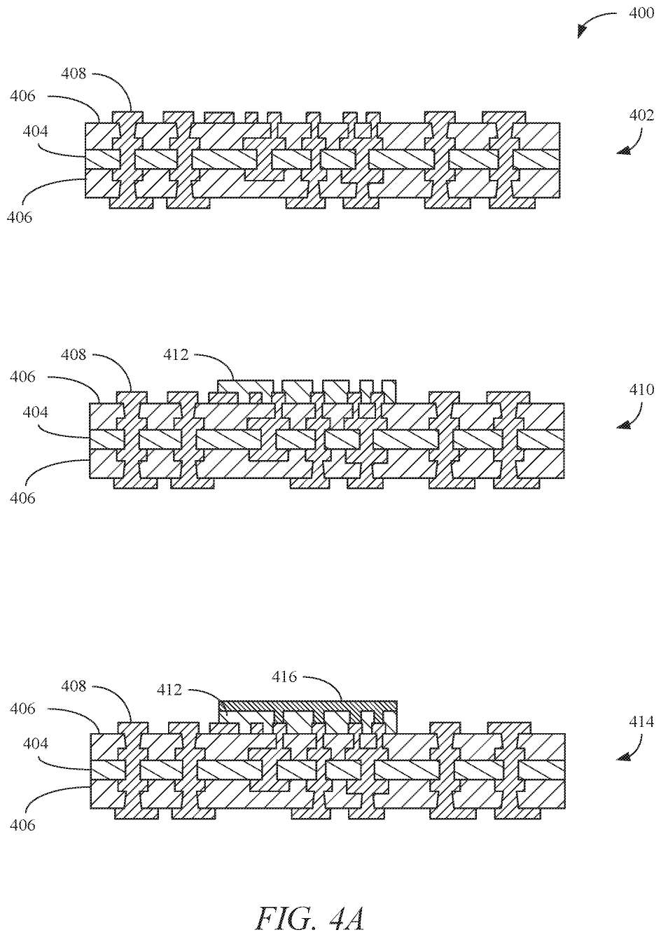

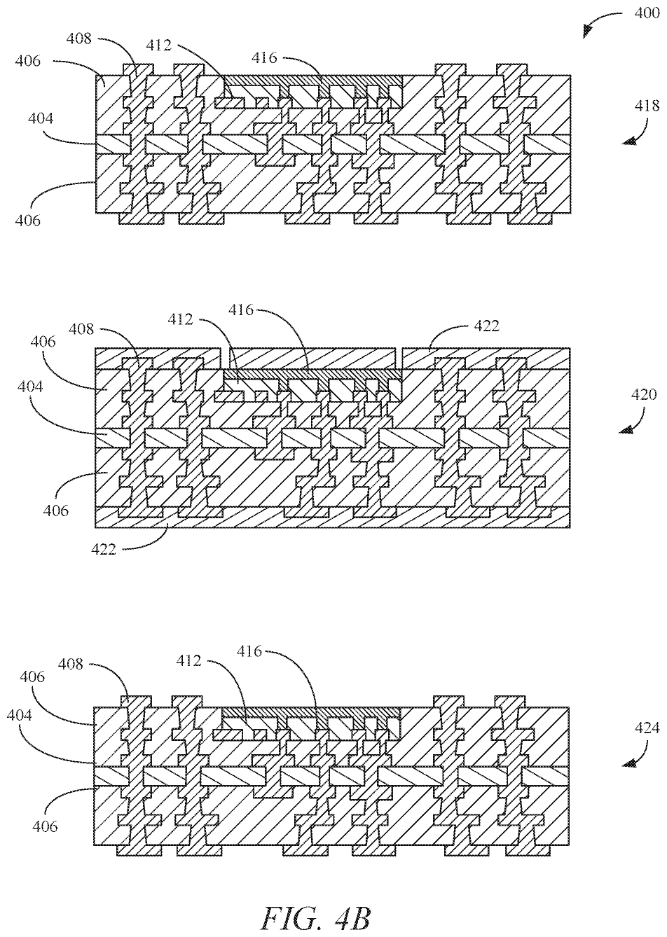

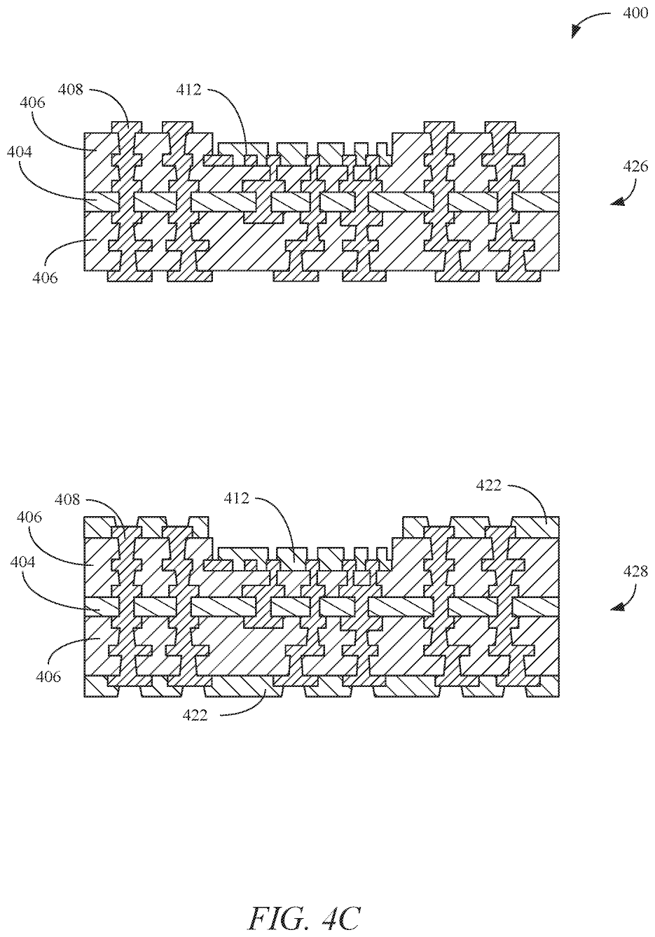

The computing device 112 may include a computing environment 202, which may include a processor 206 and a memory unit 208. The memory unit 208 may include a software module 210, plasma data 212, and cavity data 214. While executing on the processor 206, the software module 210, the plasma data 112, and the cavity data 214 may perform processes for creating a cavity within a substrate, including, for example, one or more stages included in methods 300 and 400 described below with respect to FIGS. 3 and 4.

The plasma data 212 may include data concerning the plasma 120 and the gases used to form the plasma 120. For example, the plasma data 212 may include gas compositions (ration of reaction gas to carrier gas, etc.), gas pressures (including partial pressures), operating temperatures, voltages, etc.

The cavity data 214 may include data concerning the substrate 104 and the plasma 120. For example, the cavity data 214 may include which plasma gas and which concentrations are needed for a given substrate material, translation speeds for the plasma jet 114 and/or platform 110 to achieve a desired cavity depth, etc.

The computing device 112 may also include a user interface 216. The user interface 216 may include any number of devices that allow a user to interface with the computing device 112. Non-limiting examples of the user interface 216 may include a keypad, a microphone, a speaker, a display (touchscreen or otherwise), etc.

The computing device 112 may also include a communication port 218. The communication port 218 may allow the computing device 112 to communicate with information systems and other computing devices on a network. Non-limiting examples of the communications port 218 may include, Ethernet cards (wireless or wired), Bluetooth® transmitters and receivers, near-field communications modules, etc.

The computing device 112 may also include an input/output (I/O) interface 220. The I/O interface 220 may allow the computing device 112 to receive and output information. For example, the I/O interface may allow the computing device to send and receive signals from the platform 110, the plasma jet 114, the sensor 116, and the vacuum system 124. Non-limiting examples of the I/O device 220 may include a camera (still or video), a printer, a scanner, sensors, transducers, servos, solenoids, etc.

FIGS. 3A, 3B, and 3C illustrate an example process flow 300 for creating a cavity within a substrate in accordance with embodiments disclosed herein. The process flow 300 may begin at stage 302 where a core layer 304 having one or more buildup layers 306 are provided. As shown in FIGS. 3A, 3B, and 3C, the core layer 304 and the buildup layers 306 may include a copper structure 308. From stage 302, the process flow 300 may proceed to stage 310 where a solder resist 312 may be applied to one or more of the buildup layers 306. For example, the solder resist 312 may be applied to a buildup layer 306 were a cavity is to be formed using a plasma as disclosed herein.

From stage 310, the process flow 300 may proceed to stage 314 where paste 316 may be applied to the solder resist 312. The paste 316 may act as a release layer as disclosed herein. From stage 314, the process flow 300 may proceed to stage 318 where subsequent buildup layers 306 may be added. In addition, at stage 318 additional pattern plating and eless copper layers may be added. From stage 318, the process flow 300 may proceed to stage 320 where a dry film resist layer 322 may be added. At stage 320, the dry film resist 322 may also be patterned. For example, the dry film resist 322 may be patterned to pattern an eless copper material as is known in the art.

From stage 320, the process flow 300 may proceed to stage 324 where a portion of the buildup layer 306 and the dry film resist 322 may be removed by a plasma as described herein. For example, any eless copper plating or layers may act as a metal mask. Thus, as the plasma 120 is created at the surface of the substrate 104 (i.e., the buildup layer 306), the eless copper protects the substrate 104 from the plasma 120 and only the portions of the substrate 104 exposed to the plasma 120 are removed, thereby creating a void or cavity within the substrate 104. Because the plasma 120 removes portions of the buildup layer 306, the depth of the cavity may also be controlled by the thickness of the buildup layer 306. At stage 324, the computing device 112 may receive signals from the sensor 116, plasma jet 114, etc. As disclosed above, the signals may be used to alter a flow of plasma gases to maintain conditions for the reaction between the plasma 120 and the buildup layer 306.

From stage 324, the process flow 300 may proceed to stage 326 where a solder resist layer 328 maybe applied. At stage 330 the solder resist layer 328 may be patterned using techniques known in the art. At stage 332, the cavity cap may be removed from the release layer (i.e., paste 316). In addition, the paste 316 may be removed to reveal the cavity. From stage 332, the die 334 may be sent so that surface finishing may be performed on the pads and microball process performed as known in the art to finalize production of the die 334.

FIGS. 4A, 4B, and 4C illustrate an example process flow 400 for creating a cavity within a substrate in accordance with embodiments disclosed herein. The process flow 400 may begin at stage 402 where a core layer 404 having one or more buildup layers 406 are provided. As shown in FIGS. 4A, 4B, and 4C, the core layer 404 and the buildup layers 406 may include a copper structure 408. From stage 402, the process flow 400 may proceed to stage 410 where a solder resist 412 may be applied to one or more of the buildup layers 406. For example, the solder resist 412 may be applied to a buildup layer 406 were a cavity is to be formed using a plasma as disclosed herein.

From stage 410, the process flow 400 may proceed to stage 414 where paste 416 may be applied to the solder resist 412. The paste 416 may act as a release layer as disclosed herein. From stage 414, the process flow 400 may proceed to stage 418 where subsequent buildup layers 406 may be added. In addition, at stage 418 additional pattern plating and eless copper layers may be added. From stage 418, the process flow 400 may proceed to stage 420 where a dry film resist layer 422 may be added. At stage 420, the dry film resist 422 may also be patterned. For example, the dry film resist 422 may be patterned to pattern an eless copper material as is known in the art.

From stage 420, the process flow 400 may proceed to stage 424 where a portion of the buildup layer 406 and the dry film resist 422 may be removed by a plasma as described herein. For example, any eless copper plating or layers may act as a metal mask. Thus, as the plasma 120 is created at the surface of the substrate 104 (i.e., the buildup layer 406), the eless copper protects the substrate 104 from the plasma 120 and only the portions of the substrate 104 exposed to the plasma 120 are removed, thereby creating a void or cavity within the substrate 104. Because the plasma 120 removes portions of the buildup layer 406, the depth of the cavity may also be controlled by the thickness of the buildup layer 406. At stage 424, the computing device 112 may receive signals from the sensor 116, plasma jet 114, etc. As disclosed above, the signals may be used to alter a flow of plasma gases to maintain conditions for the reaction between the plasma 120 and the buildup layer 406.

From stage 424, the process flow 400 may proceed to stage 426 where the eless copper may be flash etched and the paste 416 used as the release layer may be stripped away to reveal the cavity. From stage 426, the process flow 400 may proceed to stage 428, where a stencil print solder mask 426 may be applied with solder resist as needed. From stage 428, the die 434 may be sent so that surface finishing may be performed on the pads and microball process performed as known in the art to finalize production of the die 434.

As disclosed herein, the flow processes 300 and 400 different from laser cutting and drilling. Specifically, laser cutting and drilling stages are replaced with a plasma etching process to make the cavity cut and cap removal. Surface finishes such as ENEPIG, ENIG, OSP, etc can be used. Following surface finishing processes, dies may proceed to a traditional bumping process (e.g., microball, reflow, deflux) for die completion.

As disclosed herein, using a plasma to create a cavity may allow the cavity to be produced without the need for a metal stop layer. For example, using laser drilling requires a metal stop layer to keep the laser from penetrating too far into the substrate. By using a plasma process as described herein, the cavity can be formed without the metal layer. As a result, the space within a microelectronics package or die that was previously occupied by the metal stop layer can now include routing traces or be omitted to reduce a height of the package.

### Additional Notes & Examples

Example 1 is a microelectronics package comprising: a core layer; and a buildup layer adjacent to the core layer, the buildup layer including micro vias filled with an electrically conductive material, wherein the buildup layer defines a cavity having a plurality of sides, the plurality of sides defined by the buildup layer.

In Example 2, the subject matter of Example 1 optionally includes wherein the microelectronics package is void of a metal stop layer used to define a depth of the cavity.

In Example 3, the subject matter of any one or more of Examples 1-2 optionally include wherein the buildup layer is an organic material reactable with at least one of fluorine, tetrafluorornethane, methane, and ammonia.

In Example 4, the subject matter of any one or more of Examples 1-3 optionally include a release layer adjacent a first surface of the buildup layer, the first surface opposite a second surface of the buildup layer, the cavity formed at the second surface.

In Example 5, the subject matter of any one or more of Examples 1-4 optionally include wherein a routing layer adjacent the cavity.

Example 6 is a method for creating a cavity in a substrate, the method comprising:

passing a plasma gas over a first surface of the substrate, the plasma gas including a reactant gas and a carrier gas; and removing a portion of the substrate by reacting the reactant gas with a constituent of the first surface of the substrate.

In Example 7, the subject matter of Example 6 optionally includes removing a product of a reaction between the reactant gas and the substrate from a vicinity of the first surface of the substrate.

In Example 8, the subject matter of any one or more of Examples 6-7 optionally include wherein the reactant gas comprises at least one of fluorine, tetrafluoromethane, methane, and ammonia.

In Example 9, the subject matter of any one or more of Examples 6-8 optionally include wherein reacting the reactant gas with the constituent of the substrate includes reacting the reactant gas with the constituent without a metal layer proximate the first surface of the substrate.

In Example 10, the subject matter of any one or more of Examples 6-9 optionally include applying a release layer on a second surface of the substrate, the second surface opposite the first surface of the substrate, where the release layer is applied via either paste printing or a laminated press process.

In Example 11, the subject matter of any one or more of Examples 6-10 optionally include wherein the substrate is an organic substrate.

Example 12 is a method of manufacturing a die, the method comprising: building a core layer; applying a buildup layer to the core layer, the buildup layer including micro vias filled with an electrically conductive material; forming a cavity within the buildup layer by reacting a constituent of a plasma gas with the buildup layer; and evacuating a product formed by reacting the constituent of the plasma gas with the buildup layer.

In Example 13, the subject matter of Example 12 optionally includes wherein the constituent of the plasma gas comprises at least one of fluorine, tetrafluoromethane, methane, and ammonia.

In Example 14, the subject matter of any one or more of Examples 12-13 optionally include wherein reacting the constituent of the plasma gas with the buildup layer includes reacting the constituent of the plasma gas with the buildup layer without a metal layer proximate the buildup layer.

In Example 15, the subject matter of any one or more of Examples 12-14 optionally include applying a release layer on a first surface of the buildup layer, the first surface opposite a second surface of the buildup layer, the reaction between the constituent of the plasma gas and the buildup layer occurring at the second surface.

In Example 16, the subject matter of any one or more of Examples 12-15 optionally include wherein the buildup layer is an organic buildup layer.

Example 17 is a system for creating a cavity in a substrate, the system comprising: a platform configured to hold the substrate; a plasma jet located proximate the platform and movable about the platform, the plasma jet including a nozzle arranged to direct a plasma gas at the substrate; a processor; and a memory that stores instructions that, when executed by the processor, cause the processor to: transmit a first signal to the platform or the plasma jet, the first signal configured to cause the platform and the nozzle to translate relative to another, and sending a second signal to the plasma jet to regulate a flow rate of the plasma gas.

In Example 18, the subject matter of Example 17 optionally includes wherein the plasma gas is a binary mixture.

In Example 19, the subject matter of any one or more of Examples 17-18 optionally include wherein the plasma gas includes a carrier gas selected from the group consisting of helium, neon, argon, krypton, xenon, and nitrogen.

In Example 20, the subject matter of any one or more of Examples 17-19 optionally include wherein the plasma gas includes a reactant gas and a carrier gas.

In Example 21, the subject matter of Example 20 optionally includes wherein the reactant gas comprises at least one of fluorine, tetrafluoromethane, methane, and ammonia.

In Example 22, the subject matter of any one or more of Examples 17-21 optionally include a plurality of sensors, wherein the operations further cause the processor to: receive a third signal from the plurality of sensors, and transmit a fourth signal to the plasma jet to regulate the flow rate of the plasma gas.

In Example 23, the subject matter of Example 22 optionally includes wherein the third signal indicates a pressure proximate the nozzle the platform; and the fourth signal increases or decreases the flow rate of the plasma gas depending on the pressure.

In Example 24, the subject matter of any one or more of Examples 22-23 optionally include wherein the third signal indicates a composition of the plasma gas, and the fourth signal increases or decreases a flow rate of a constituent component of the plasma gas.

In Example 25, the subject matter of any one or more of Examples 17-24 optionally include wherein the substrate is an organic substrate.

Example 26 is a system for creating a cavity in a substrate, the system comprising: means for creating a plasma gas; means for directing the plasma gas onto a surface of the substrate; and means for evacuating a reaction product, the reaction product created by a reaction of a constituent of the plasma gas and the substrate.

In Example 27, the subject matter of Example 26 optionally includes means for regulating a flow rate of the plasma gas onto the surface of the substrate.

In Example 28, the subject matter of any one or more of Examples 26-27 optionally include means for controlling a composition of the plasma gas.

In Example 29, the subject matter of any one or more of Examples 26-28 optionally include wherein the plasma gas includes a reactant gas and a carrier gas.

In Example 30, the subject matter of Example 29 optionally includes wherein the carrier gas is selected from the group consisting of: helium, neon, argon, krypton, xenon, and nitrogen.

In Example 31, the subject matter of any one or more of Examples 29-30 optionally include wherein the reactant gas comprises at least one of fluorine, tetrafluoromethane, methane, and ammonia.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplate are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the turns “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. However, the claims may not set forth features disclosed herein because embodiments may include a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

1-24. (canceled)

25. A microelectronics package comprising:
a core layer; and
a buildup layer adjacent to the core layer, the buildup layer including micro vias filled with an electrically conductive material,
wherein the buildup layer defines a cavity having a plurality of sides, the plurality of sides defined by the buildup layer.

26. The microelectronics package of claim 25, wherein the microelectronics package is void of a metal stop layer used to define a depth of the cavity.

27. The microelectronics package of claim 25, wherein the buildup layer is an organic material reactable with at least one of fluorine, tetrafluoromethane, methane, and ammonia.

28. The microelectronics package of claim 25, further comprising a release layer adjacent a first surface of the buildup layer, the first surface opposite a second surface of the buildup layer, the cavity formed at the second surface.

29. The microelectronics package of claim 25, wherein a routing layer adjacent the cavity.

30. A method for creating a cavity in a substrate, the method comprising:
passing a plasma gas over a first surface of the substrate, the plasma gas including a reactant gas and a carrier gas; and
removing a portion of the substrate by reacting the reactant gas with a constituent of the first surface of the substrate.

31. The method of claim 30, further comprising removing a product of a reaction between the reactant gas and the substrate from a vicinity of the first surface of the substrate.

32. The method of claim 30, wherein the reactant gas comprises at least one of fluorine, tetrafluoromethane, methane, and ammonia.

33. The method of claim 30, wherein reacting the reactant gas with the constituent of the substrate includes reacting the reactant gas with the constituent without a metal layer proximate the first surface of the substrate.

34. The method of claim 30, further comprising applying a release layer on a second surface of the substrate, the second surface opposite the first surface of the substrate, where the release layer is applied via either paste printing or a laminated press process.

35. The method of claim 30, wherein the substrate is an organic substrate.

36. A method of manufacturing a die, the method comprising:
building a core layer;
applying a buildup layer to the core layer, the buildup layer including micro vias filled with an electrically conductive material;
forming a cavity within the buildup layer by reacting a constituent of a plasma gas with the buildup layer; and
evacuating a product formed by reacting the constituent of the plasma gas with the buildup layer.

37. The method of claim 36, wherein the constituent of the plasma gas comprises at least one of fluorine, tetrafluoromethane, methane, and ammonia.

38. The method of claim 36, wherein reacting the constituent of the plasma gas with the buildup layer includes reacting the constituent of the plasma gas with the buildup layer without a metal layer proximate the buildup layer.

39. The method of claim 36, further comprising applying a release layer on a first surface of the buildup layer, the first surface opposite a second surface of the buildup layer, the reaction between the constituent of the plasma gas and the buildup layer occurring at the second surface.

40. The method of claim 36, wherein the buildup layer is an organic buildup layer.

41. A system for creating a cavity in a substrate, the system comprising:
a platform configured to hold the substrate;
a plasma jet located proximate the platform and movable about the platform, the plasma jet including a nozzle arranged to direct a plasma gas at the substrate;
a processor; and
a memory that stores instructions that, when executed by the processor, cause the processor to:
transmit a first signal to the platform or the plasma jet, the first signal configured to cause the platform and the nozzle to translate relative to another, and
sending a second signal to the plasma jet to regulate a flow rate of the plasma gas.

42. The system of claim 41, wherein the plasma gas is a binary mixture.

43. The system of claim 41, wherein the plasma gas includes a carrier gas selected from the group consisting of: helium, neon, argon, krypton, xenon, and nitrogen.

44. The system of claim 41, wherein the plasma gas includes a reactant gas and a carrier gas.

45. The system of claim 44, wherein the reactant gas comprises at least one of fluorine, tetrafluoromethane, methane, and ammonia.

46. The system of claim 41, further comprising a plurality of sensors, wherein the operations further cause the processor to:
receive a third signal from the plurality of sensors, and
transmit a fourth signal to the plasma jet to regulate the flow rate of the plasma gas.

47. The system of claim 46, wherein
the third signal indicates a pressure proximate the nozzle the platform; and
the fourth signal increases or decreases the flow rate of the plasma gas depending on the pressure.

48. The system of claim 46, wherein
the third signal indicates a composition of the plasma gas, and
the fourth signal increases or decreases a flow rate of a constituent component of the plasma gas.

49. The system of claim 41, wherein the substrate is an organic substrate.
